(19) United States
(12) Patent Application Publication
(10) Pub. No.: US 2026/0011817 A1
(43) Pub. Date: Jan. 8, 2026

(54) MODULES AND PACKS FOR SOLID-STATE RECHARGEABLE BATTERIES

(71) Applicant: QuantumScape Battery, Inc., San Jose, CA (US)

(72) Inventors: William GARDNER, San Jose, CA (US); Timothy Holme, San Jose, CA (US); William Hudson, San Jose, CA (US); Celina Mikolajczak, San Jose, CA (US); Richard Anthony Slagle, San Jose, CA (US); Shandor Daroczi, San Jose, CA (US)

(21) Appl. No.: 19/325,228

(22) Filed: Sep. 10, 2025

Related U.S. Application Data
(63) Continuation of application No. PCT/US2024/021533, filed on Mar. 26, 2024.
(60) Provisional application No. 63/492,629, filed on Mar. 28, 2023.

(51) Int. Cl. H01M 10/656; G01R 31/387; G01R 31/392; H01M 10/625; H01M 50/211; H01M 50/242; H01M 50/249

(52) U.S. Cl. CPC H01M 10/656; G01R 31/387; G01R 31/392; H01M 50/211; H01M 50/242; H01M 50/249; H01M 10/625

(57) ABSTRACT

Provided herein is a module with at least two electrochemical stack assemblies (ESA), wherein each ESA individually, in each instance, includes one or more electrochemical cells, each electrochemical cell including a solid-state electrolyte; a frame surrounding the one or more electrochemical cells; and a laminated pouch surrounding the frame and the one or more electrochemical. Also set forth herein are methods of making and using the same.

### CROSS-REFERENCE TO RELATED APPLICATIONS

This application claims priority to, and the benefit of, U.S. Provisional Patent Application No. 63/492,629, filed Mar. 28, 2023, the entire contents of which are herein incorporated by reference in their entirety for all purposes.

### FIELD

The present application relates to modules, packs, and related enclosures for rechargeable batteries, particularly solid-state lithium batteries.

### BACKGROUND

Solid-state lithium batteries have a number of advantages over conventional lithium batteries that rely solely on liquid-based electrolytes. However, solids by their very nature are less deformable than liquids, making packaging solid-state lithium batteries more challenging.

One challenge associated with packaging solid-state lithium batteries having a lithium-metal anode is that the batteries expand and contract during charge and discharge cycles. It would be desirable to provide packaging that accommodates this expansion and contraction without adversely affecting battery performance.

### SUMMARY

In an example, set forth herein is a module comprising at least two electrochemical stack assemblies (ESA), wherein each ESA individually, in each instance, comprises: one or more electrochemical cells, each electrochemical cell comprising a solid-state electrolyte; a frame surrounding the one or more electrochemical cells; and a laminated pouch surrounding the frame and the one or more electrochemical cells.

In another example, set forth herein is a method of determining state-of-charge (SOC), comprising, measuring the thickness of a laminated pouch in a module set forth herein, wherein the thickness is proportional to the SOC; and determining SOC based on the measured thickness.

In another example, set forth herein is a method of pumping a coolant, comprising providing a module set forth herein, wherein between laminated pouches there is a compressible cooling pouch or pocket containing cooling fluid and coupled to a cooling system; expanding and contracting the laminated pouches by charging and discharging the electrochemical cells therein; and using mechanical force created by the expansion and contraction of one or more of the laminated pouches as lithium metal plates at the anode accumulates during a charge and strips during a discharge. The expansion and contraction pumps the cooling fluid.

In another example, set forth herein is a method of cooling a module set forth herein, comprising drawing heat from the ESA through the edges of the laminated pouches. This is referred to as edge-cooling of the laminated pouches.

In another example, set forth herein is a method of cooling a module set forth herein, comprising drawing heat from the electrochemical cells through the sides (which are often called faces or major surfaces) of the laminated pouches. This is referred to as face-cooling of the laminated pouches.

### BRIEF DESCRIPTION OF THE DRAWINGS

FIG. 1 shows a laminated pouch according to an embodiment.

FIGS. 2 to 5 are exploded views of a laminated pouch according to embodiments.

FIGS. 6 and 7 are diagrams of a module according to embodiments.

### DETAILED DESCRIPTION

### Definitions

As used herein, the term “about,” when qualifying a number, e.g., about 15 weight percent (% w/w), refers to the number qualified and optionally the numbers included in a range about that qualified number that includes ±10% of the number. For example, about 15% w/w includes 15% w/w as well as 13.5% w/w, 14% w/w, 14.5% w/w, 15.5% w/w, 16% w/w, or 16.5% w/w. For example, “about 75° C.,” includes 75° C. as well as 67° C., 68° C., 69° C., 70° C., 71° C., 72° C., 73° C., 74° C., 75° C., 76° C., 77° C., 78° C., 79° C., 80° C., 81° C., 82° C., or 83° C.

As used herein, “selected from the group consisting of” refers to a single member from the group, more than one member from the group, or a combination of members from the group. For example, a member selected from the group consisting of A, B, and C can include A only, B only, or C only, as well as A and B, A and C, B and C, as well as A, B, and C.

As used herein, the phrases “electrochemical cell” or “battery cell” shall, unless specified to the contrary, mean a single cell including a positive electrode and a negative electrode, which have ionic communication with each other by way of an electrolyte. In some embodiments, a battery or module may include multiple positive electrodes and/or multiple negative electrodes enclosed in one container or otherwise put together one on top of another, e.g., a stack of electrochemical cells. A stack of electrochemical cells or “electrochemical stack,” may be referred to as a multi-layered cell. A symmetric cell may be a cell having two Li metal anodes separated by a solid-state electrolyte.

As used herein, “module” and “battery module” mean a unit that houses one or more electrochemical cells and may, but does not necessarily, include the following elements: (i) mechanical structural components (e.g., outer module housing/structure, means for spacing and securing the cells, cell pressure distributors, cell swelling compensation); (ii) thermal management components (e.g., battery cell thermal contacts/interface, venting, cooling channels, and thermal barriers, all at least partially within the module housing); (iii) high voltage components (e.g., busbars, cables, couplings, electrical insulation, and terminals, all at least partially enclosed by the module housing); and (iv) electrical hardware components for cell monitoring and identification (e.g., cell supervision electronics, electrical connectors, wireless or wired communication devices, RFIDs, thermocouples, current sensors, and voltage sensors). An electrochemical stack may include several of these aforementioned units arranged in electrical communication (e.g., serial or parallel electrical connection). In some examples, when the electrochemical stack includes several units, the units may be layered, laminated together, or otherwise adhered to each other, in a column. In some examples, when the electrochemical stack includes several units, the units may be layered, laminated together, or otherwise adhered to each other in an array. In some examples, when the electrochemical stack includes several units, the stack may be arranged such that one negative electrode current collector is shared with two or more negative electrodes. That is, two or more negative electrodes may be attached to a single negative electrode current collector. Alternatively, in some examples, when the electrochemical stack includes several units, the stack may be arranged such that one positive electrode current collector is shared with two or more positive electrodes. That is, two or more positive electrodes may be attached to a single positive electrode current collector. Where appropriate or necessary, adhesives or other bonding materials may be provided among the various layers in a stack. Optionally or additionally, when cells are provided together to form a stack, the cells simply may be set one on top of another, or alternatively one or more of the cells may be adhered to one or both immediately adjacent cells.

Electrochemical stack assemblies refer to multiple electrochemical cells connected together.

As used herein, the phrase “positive electrode” refers to the electrode in a secondary battery towards which positive ions, e.g., Li⁺, conduct, flow, or move during discharge of the battery. As used herein, the phrase “negative electrode” refers to the electrode in a secondary battery from which positive ions, e.g., Li⁺ flow, or move during discharge of the battery. In a battery comprised of a Li-metal electrode and a conversion chemistry, intercalation chemistry, or combination of conversion/intercalation chemistry-including electrode (i.e., cathode active material), the electrode having the conversion chemistry, intercalation chemistry, or combination of conversion/intercalation chemistry material is referred to as the positive electrode. In some usage, cathode is used in place of positive electrode, and anode is used in place of negative electrode. When a Li-secondary battery is charged, Li ions move from the positive electrode (e.g., nickel fluoride (NiFₓ, where x is from 0 to 2.5), nickel manganese cobalt oxide (NMC), nickel cobalt aluminum oxide (NCA)) towards the negative electrode (e.g., Li-metal). When a Li-secondary battery is discharged, Li ions move towards the positive electrode and from the negative electrode.

As used herein, the phrase “positive electrode terminal” refers to an electrical connection to the positive electrode. A positive electrode terminal may also be referred to as a positive electrode current collector.

As used herein, the phrase “negative electrode terminal” refers to an electrical connection to the negative electrode. A negative electrode terminal may also be referred to as a negative electrode current collector.

As used herein, the phrase “cathode active material” refers to a material which can intercalate lithium ions or react with lithium ions in a reversible manner. Examples include LiMPO₄ (M═Fe, Ni, Co, Mn); LiₓTi_{y}O_{z}, wherein x is from 0 to 8, y is from 1 to 12, z is from 1 to 24; LiMn₂ₐNiₐO₄, wherein a is from 0 to 2; a nickel cobalt aluminum oxide; LiNiₓMn_{y}Co_{z}O₂, wherein x+y+z=1, and 0≤x≤1, 0≤y≤1, and 0≤z≤1; and LiNiₓCo_{y}Al₂O₂, wherein x+y+z=1, and 0≤x≤1, 0≤y≤1, and 0≤z≤1. In these formula, x, y, and z are chosen so that the formula is charge neutral.

As used herein, the phrase “solid-state electrolyte separator” is used interchangeably with the phrase “solid separator,” and refers to a material which does not include carbon and which conducts atomic ions (e.g., Li⁺) but does not conduct electrons. A solid-state electrolyte separator is a solid material suitable for electrically isolating the positive and negative electrodes of a lithium secondary battery while also providing a conduction pathway for lithium ions. Examples of solid-state electrolytes include oxide electrolytes and sulfide electrolytes, which are further defined below. Non-limiting examples of sulfide electrolytes are found, for example, in U.S. Pat. No. 9,172,114, which issued Oct. 27, 2015, and also in US Patent Application Publication No. 2017-0162901 A1, which published Jun. 8, 2017. Non-limiting examples of oxide electrolytes are found, for example, in US Patent Application Publication No. 2015-0200420 A1, which published Jul. 16, 2015, and issued as U.S. Pat. No. 9,806,372 on Oct. 31, 2017. In some examples, the solid-state electrolyte also includes a polymer and is referred to as a composite electrolyte. Composite electrolytes are found for example in U.S. Pat. No. 10,374,254, which issued Aug. 6, 2019. The entire contents of the just-mentioned US patents and published US patent applications are incorporated herein by reference in their entirety for all purposes.

As used herein, the terms “separator” is a short-hand reference for Li⁺ion-conducting separator, unless explicitly specified otherwise.

As used herein, the terms “side” or “edge” or “edge surface” or “minor surface” may be used interchangeably to refer to sides or side edges of an electrochemical cell stack, a frame, or a prismatic-frame-in-pouch. There may be a “side edge” of a prismatic frame-in-pouch, for example, which is perpendicular to a “bottom edge” of the prismatic frame-in-pouch.

As used herein, the terms “face” or “major surface” may be used interchangeably to refer to a major surface of an electrochemical cell stack, a frame, or a prismatic-frame-in-pouch, in contrast to an “edge” or an “edge surface” or a “minor surface,” any of which will have substantially less surface area than will a major surface. In some instances, depending on orientation of the electrochemical stack, a major surface may be a top major surface or a bottom major surface. A “top surface” or “top major surface” generally will be opposed to a “bottom surface” or a “bottom major surface”.

As used herein, the phrase “thickness” or “film thickness” refers to the distance, or median measured distance between top and bottom major surfaces of a layer or film. As used herein, the top and bottom major surfaces refer to the surfaces of a layer or film having the largest geometric surface area. By way of non-limiting example, as used herein, a layer having dimensions of 64×79 mm and a thickness of 1 μm-100 μm will have its thickness measured as distance between the top and bottom major surfaces, each of which has a dimension of 64×79 mm.

As used herein, “thin” means, when qualifying a solid-state electrolyte, a thickness dimension less than 200 μm, sometimes less than 100 μm and in some cases between 0.1 and 60 μm, and in other cases between about 10 nm to about 100 μm; in other cases about 1μm, 10 μm, or 50 μm in thickness.

As used herein, the phrase “laminate conforms around the frame” refers to the pliability of the laminate to surround and encapsulate the frame without a significant amount of space being present between the laminate and the frame where the laminate does not contact the frame. In some examples, the laminate will be in intimate contact with the frame, particularly when the pouch is under vacuum or internal pressure sufficiently less than external pressure or ambient atmospheric pressure.

In some examples herein, a laminate over frame assembly comprises at least one electrochemical cell which in turn includes at least one positive electrode terminal and at least one negative electrode terminal; at least one electrochemical stack comprising a solid-state electrolyte; the electrochemical cell has a top major surface, a bottom major surface, and four minor surfaces; a laminated pouch; and a frame contained within the laminated pouch and surrounding the at least one electrochemical stack; wherein: the frame does not contact the four minor surfaces; and the laminated pouch contacts the top major surface and bottom major surface.

As used herein, the phrase “pre-formed shape of the laminated pouch” means a shape made in the laminate. In some examples, the laminate is manufactured from a flat sheet form which is placed in a pneumatic press. A die and a cavity are used to transform the flat sheet into a pre-formed shape. This includes debossing the form to raise part of the laminate up and away from the laminate surface at the edge of the flat sheet, as well as embossing the form to push part of the laminate down and away from the laminate surface at the edge of the flat sheet. In some examples, a combination of deboss and emboss is used to form the shape in the laminate. By forming a shape in the laminate, the laminate does not need to deform much, if at all, against the top or bottom major surface of the electrochemical stack. When vacuum is applied, the sealed laminate will be pushed onto, and will take the shape of the frame and the cell stack, due to atmospheric pressure outside the laminate being higher than the pressure inside the laminae. In some examples, the laminate is formed into the shape of the electrochemical stack at 0% state-of-charge. The laminate is thus pre-stressed during its manufacture so no stress is concentrated on the electrochemical stack when the laminate is stretched over the frame. As the laminate is pulled over the frame, a draft angle is present as the laminate stretches over the frame. This draft angle, is part, provides space between the laminate and the electrochemical stack so that the laminate only contacts the top or bottom major surfaces of the electrochemical stack. When a vacuum is pulled on the sealed laminate, the draft angles collapse against the frame but not against the minor surfaces of the electrochemical stack. After pulling a vacuum in the sealed laminate, the pre-formed portion of the laminate will take the shape of the frame.

As used herein, the phrase “lithium stuffed garnet” refers to oxides that are characterized by a crystal structure related to a garnet crystal structure. U.S. Patent Application Publication No. U.S. 2015/0099190, which published Apr. 9, 2015, is incorporated by reference herein in its entirety for all purposes. This application describes Li-stuffed garnet solid-state electrolytes used in solid-state lithium rechargeable batteries.

Unless stated otherwise to the contrary, lithium-stuffed garnets include compounds having the formula Li_{A}La_{B}M′_{C}M″_{D}Zr_{E}O_{F}, Li_{A}La_{B}M′_{C}M″_{D}Ta_{E}O_{F}, or Li_{A}La_{B}M′_{C}M″_{D}Nb_{E}O_{F}, wherein 4<A<8.5, 1.5<B<4,0≤C≤2, 0≤D≤2; 0≤E≤2, 10<F<13, and M″ and M″ are each, independently in each instance selected from Al, Mo, W, Nb, Sb, Ca, Ba, Sr, Ce, Hf, Rb, Nb, Ga, or Ta, or LiₐLa_{b}Zr_{c}Al_{d}Me″ₑO_{f}, wherein 5<a<7.7; 2<b<4; 0≤c≤2.5; 0≤d≤2; 0≤e≤2, 10<f<13 and Me″ is a metal selected from Nb, Ta, V, W, Mo, Ga, or Sb and as described herein.

Li-stuffed garnets may also be a composition according to Li_{A}La_{B}M′_{C}M″_{D}Zr_{E}O_{F}, Li_{A}La_{B}M′_{C}M″_{D}Ta_{E}O_{F}, or Li_{A}La_{B}M′_{C}M″_{D}Nb_{E}O_{F}, wherein 4<A<8.5, 1.5<B<4,0<C<2,0≤D<2; 0≤E<3, 10<F<13, and M′ and M″ are each, independently in each instance selected from Ga, Al, Mo, W, Nb, Sb, Ca, Ba, Sr, Ce, Hf, Rb, Nb, Ga, or Ta, or LiₐLa_{b}Zr_{c}Al_{d}Me″ₑO_{f}, wherein 5<a<8.5; 2<b<4; 0<c≤2.5; 0≤d<2; 0≤e<2, and 10<f<13 and Me″ is a metal selected from Ga, Nb, Ta, V, W, Mo, or Sb and as otherwise described in U.S. Patent Application Publication No. U.S. 2015/0099190. As used herein, lithium-stuffed garnets, and garnets, generally, include, but are not limited to, Li_{7.0}La₃(Zrₜ₁+Nbₜ₂+Taₜ₃)O₁₂+0.35Al₁₂O₃; wherein (t1+t2+t3=2) so that the La:(Zr/Nb/Ta) ratio is 3:2. Also, garnets used herein include, but are not limited to, LiₓLa₃Zr₂O_{F}+yAl₂O₃, wherein x ranges from 5.5 to 9; and y ranges from 0.05 to 1. In these examples, subscripts x and y are selected so that the garnet is charge neutral. In some examples x is 7 and y is 1.0. In some examples, x is 5 and y is 1.0. In some examples, x is 6 and y is 1.0. In some examples, x is 8 and y is 1.0. In some examples, x is 9 and y is 1.0. In some examples x is 7 and y is 0.35. In some examples, x is 5 and y is 0.35. In some examples, x is 6 and y is 0.35. In some examples, x is 8 and y is 0.35. In some examples, x is 9 and y is 0.35. In some examples x is 7 and y is 0.7. In some examples, x is 5 and y is 0.7. In some examples, x is 6 and y is 0.7. In some examples, x is 8 and y is 0.7. In some examples, x is 9 and y is 0.7. In some examples x is 7 and y is 0.75. In some examples, x is 5 and y is 0.75. In some examples, x is 6 and y is 0.75. In some examples, x is 8 and y is 0.75. In some examples, x is 9 and y is 0.75. In some examples x is 7 and y is 0.8. In some examples, x is 5 and y is 0.8. In some examples, x is 6 and y is 0.8. In some examples, x is 8 and y is 0.8. In some examples, x is 9 and y is 0.8. In some examples x is 7 and y is 0.5. In some examples, x is 5 and y is 0.5. In some examples, x is 6 and y is 0.5. In some examples, x is 8 and y is 0.5. In some examples, x is 9 and y is 0.5. In some examples x is 7 and y is 0.4. In some examples, x is 5 and y is 0.4. In some examples, x is 6 and y is 0.4. In some examples, x is 8 and y is 0.4. In some examples, x is 9 and y is 0.4. In some examples x is 7 and y is 0.3. In some examples, x is 5 and y is 0.3. In some examples, x is 6 and y is 0.3. In some examples, x is 8 and y is 0.3. In some examples, x is 9 and y is 0.3. In some examples x is 7 and y is 0.22. In some examples, x is 5 and y is 0.22. In some examples, x is 6 and y is 0.22. In some examples, x is 8 and y is 0.22. In some examples, x is 9 and y is 0.22. Also, garnets as used herein include, but are not limited to, LiₓLa₃Zr₂O_{12+y}Al₂O₃. In one embodiment, the Li-stuffed garnet herein has a composition of Li₇Li₃Zr₂O₁₂. In another embodiment, the Li-stuffed garnet herein has a composition of Li₇Li₃Zr₂O₁₂·Al₂O₃. In yet another embodiment, the Li-stuffed garnet herein has a composition of Li₇Li₃Zr₂O₁₂·0.22Al₂O₃. In yet another embodiment, the Li-stuffed garnet herein has a composition of Li₇Li₃Zr₂O₁₂·0.35Al₂O₃. In certain other embodiments, the Li-stuffed garnet herein has a composition of Li₇Li₃Zr₂O₁₂·0.5Al₂O₃. In another embodiment, the Li-stuffed garnet herein has a composition of Li₇Li₃Zr₂O₁₂·0.75Al₂O₃.

As used herein, garnet does not include YAG-garnets (i.e., yttrium aluminum garnets, or, e.g., Y₃Al₅O₁₂). As used herein, garnet does not include silicate-based garnets such as pyrope, almandine, spessartine, grossular, hessonite, or cinnamon-stone, tsavorite, uvarovite and andradite and the solid solutions pyrope-almandine-spessarite and uvarovite-grossular-andradite. Garnets herein do not include nesosilicates having the general formula X₃Y₂(SiO₄)₃ wherein X is Ca, Mg, Fe, and, or, Mn; and Y is Al, Fe, and, or, Cr.

As used herein, “close-packed,” refers to a packaging arrangement which minimizes vacant space between the items being packed. A close-packed module of pouches would be a packaging of pouches which minimizes the vacant space between pouches.

As used herein, “dimensional stability,” refers to the ability of the laminated pouches to provide structural support to a module along a preferred dimension. For example, if the laminated pouches, when stacked vertically and adjacent to each other, provide mechanical support to the pouch in the same direction in which the stacks are vertically aligned, then the laminated pouches are providing dimensional stability to the module. This is just one non-limiting example. Dimensional stability may include structural support in more than one dimension but includes structural support in at least one dimension.

As used herein, a “fast charge,” is a battery charge at a rate of 4 C or higher.

As used herein, “state of charge” (SOC) includes the extent to which a given battery cell is charged or discharged with respect to the charge capacity of the battery cell. For example, when a battery cell possesses half of the capacity of a fully charged battery cell, the battery has an SOC of 50%. The percentage (%) given is made with respect to the capacity available when the battery is at maximum charge voltage. For example, a battery rated as a 100 kilowatthour (kWh) battery with a 50% SOC has 50 kWh.

As used herein, “state-of-health” (SOH) is a measurement indicative of battery degradation. More particularly, SOH is a measure of the capacity remaining in a battery relative to its original capacity. SOH is represented by a percent of the available capacity relative to the capacity of the battery as-rated or nameplate capacity. For example, after some use, a battery rated as a 100 kWh battery will fail to hold a charge of 100 kWh. If, for example, the originally rated battery could charge and discharge 100 kWh of electricity, but now can only charge and discharge 90 kWh of electricity, the battery would be characterized as having a 90% SOH.

Looking at the foregoing definitions of SOC and SOH, if a 100 kWh battery has a 90% SOH and is charged to 50% of capacity, the battery has 45 kWh.

### Modules

In an embodiment, set forth herein is a module comprising at least two electrochemical stack assemblies (ESA), wherein each ESA individually, in each instance, comprises: one or more electrochemical cells, each electrochemical cell comprising a solid-state electrolyte; a frame surrounding the one or more electrochemical cells; and a laminated pouch surrounding the frame and the one or more electrochemical. In addition to the description herein, examples of assemblies of laminated pouches surrounding a frame are set forth in International PCT Patent Application No. PCT/US22/44883, filed Sep. 27, 2022, the entire contents of which are herein incorporated by reference in its entirety for all purposes.

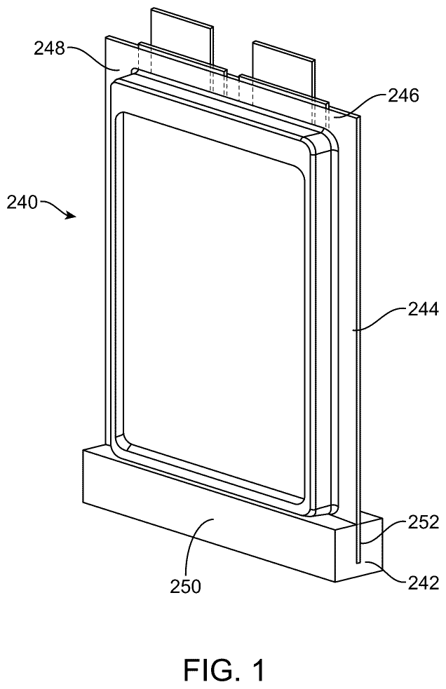

In some examples, including any of the foregoing, the module includes an alignment segment which interfaces with one or more of the edges of the laminated pouches. For example, FIG. 1 shows an edge 242 of a laminated pouch 240 may be aligned while positioning the pouch in a module, using alignment block 250 which includes a slit 252 to accommodate one of edges 242, 244, 246, and 248 of laminated pouch 240. In some examples, the edge 242 inserted into slit 252 of alignment block 250 is a side edge of laminated pouch 240. In some examples, the edge 242 inserted into slit 252 of alignment block 250 is a bottom edge of laminated pouch 240.

In an embodiment, as shown in FIG. 1, at least one side of the assembled laminated pouch, such as the side opposite the electrodes, may be left unrolled, and may be inserted into a slotted metal piece 250 to facilitate alignment or optionally heat dispersion. In an embodiment, as shown in FIG. 1, the sides of the assembled pouch may be inserted between flat metal pieces on a base to facilitate heat dispersion or alignment of the pouches.

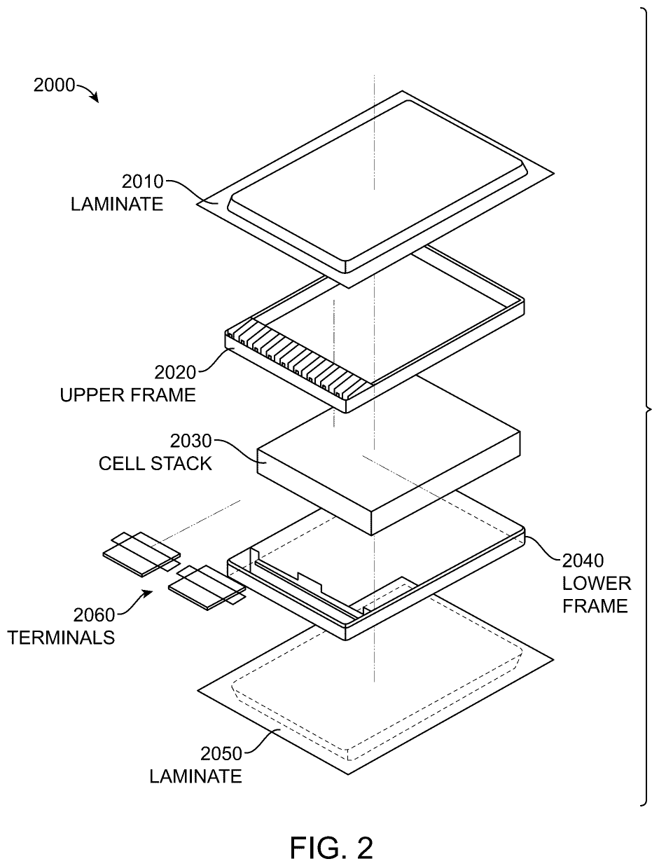

An example of a laminate over frame is shown in FIG. 2. In FIG. 2, in order from top to bottom, in assembly 2000, a top laminate portion 2010 is disposed over an upper frame portion 2020. An electrochemical stack 2030 fits between upper frame portion 2020 and a lower frame portion 2040. The upper frame portion 2020 and the lower frame portion 2040 are attached to each other to form a frame around the electrochemical stack 2030. The frame surrounds but does not contact the minor surfaces of the electrochemical stack 2030. A bottom laminate portion 2050 is disposed below the lower frame portion 2040. The top laminate portion 2010 and bottom laminate portion 2050 form a laminated pouch (sometimes referred to herein as a pre-formed laminated pouch) which surrounds the assembled frame and the electrochemical stack 2030 contained therein. The top laminate portion 2010 and bottom laminate portion 2050 are sealed together so as to form a seal around the assembled frame and the electrochemical stack 2030 contained therein.

The electrochemical stack 2030 also has terminals (positive and negative electrodes or tabs) 2060 attached respectively to the cathode and anode of the electrochemical stack 2030. The cathode and anode extend through the frame and may contact the frame. In some examples, the terminals 2060 extend through the laminated pouch. In some examples, the terminals 2060 extend through the laminated pouch and form part of the seal. The portions of the seal around each of the terminals 2060 may be thought of as separate seals, for example, in the case of a safety event which might necessitate the venting of the laminated pouch. In such a situation, instead of the entire seal around the pouch opening, one or both of the seals around respective terminals 2060 may be configured to open to enable venting.

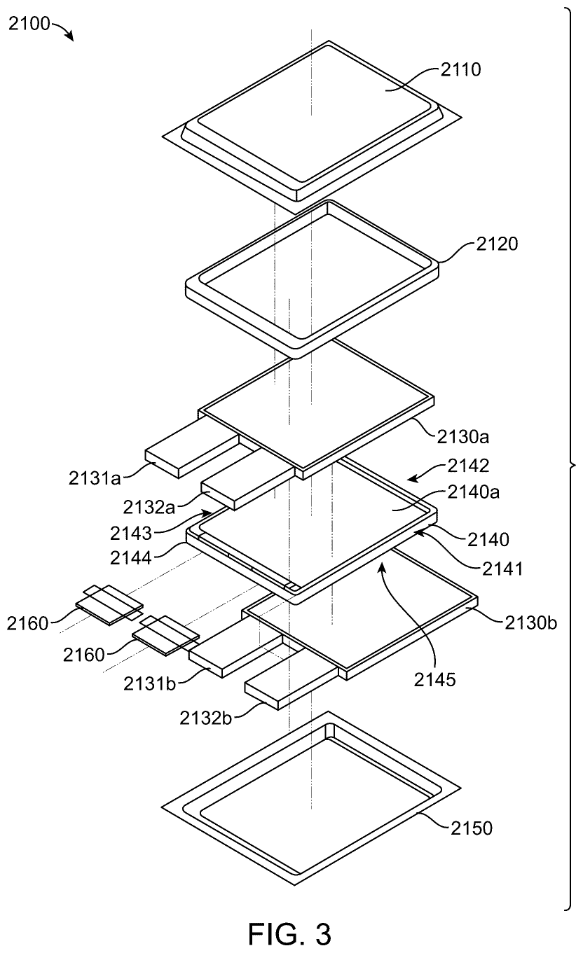

In FIG. 3, in order from top to bottom, in assembly 2100, a top laminate portion 2110 is disposed over an upper frame portion 2120. An electrochemical stack 2130a fits inside upper frame portion 2120, which is disposed above (and in an embodiment, secured to) a lower frame portion 2140. Lower frame portion 2140 has a solid portion or surface 2140a to which electrochemical stack 2130a may be bonded or otherwise attached. Lower frame portion 2140 has edges 2141-2144 extending below solid portion or surface 2140a to accommodate electrochemical stack 2130b. In an embodiment, the lower frame portion 2140 with its edges 2141-2144 form a tray-shaped structure that may be referred to elsewhere herein as a tray.

The upper frame portion 2120 and the lower frame portion 2140 are attached to each other to form a frame around the electrochemical stack 2130a. The frame surrounds but does not contact the minor surfaces of the electrochemical stack 2130a. A further electrochemical stack 2130b is disposed below surface 2140a, and may be bonded or otherwise attached to surface 2140a. The frame surrounds but does not contact the minor surfaces of the electrochemical stack 2130b. In an embodiment, electrochemical stack 2130b fits within edges 2141-2144 of lower frame portion 2140, so that the edges 2141-2144 of lower frame portion 2140 surround, but do not contact edges of electrochemical stack 2130b. A bottom laminate portion 2150 is disposed below the lower frame portion 2140. The top laminate portion 2110 and bottom laminate portion 2150 form a laminated pouch which surrounds the assembled frame and the electrochemical stacks 2130a and 2130b contained therein. The top laminate portion 2110 and bottom laminate portion 2150 are sealed together so as to form a seal around the assembled frame and the electrochemical stacks 2130a and 2130b contained therein.

The electrochemical stack 2130a also has terminals (positive and negative electrodes or tabs) 2160 attached respectively to the individual cell cathode terminals 2131a and individual cell anode terminals 2132a of the electrochemical stack 2130, and to individual cell cathode terminals 2131b and individual cell anode terminals 2132b of the electrochemical stack 2130b. These individual cell cathode terminals 2131a and 2131b, and anode terminals 2132a and 2132b extend through the frame and may contact the frame. In some examples, the terminals 2160 extend through the laminated pouch. In some examples, the terminals 2160, but not terminals 2131a and 2132b, extend through the laminated pouch and form part of the seal.

In some examples, including any of the foregoing, the frame is a structural support for the module. In some examples, the structural support is an airplane wing strut. In other examples, the structural support is a motorcycle body. In yet other examples, the structural support is a motor vehicle body. In yet other examples, the structure support is a component of a honeycomb structure. In some examples, an ESA as described herein may be used for consumer electronics, such as cellular devices, tablets, laptops, computers, wearables; electric vehicles; and electric motorcycles.

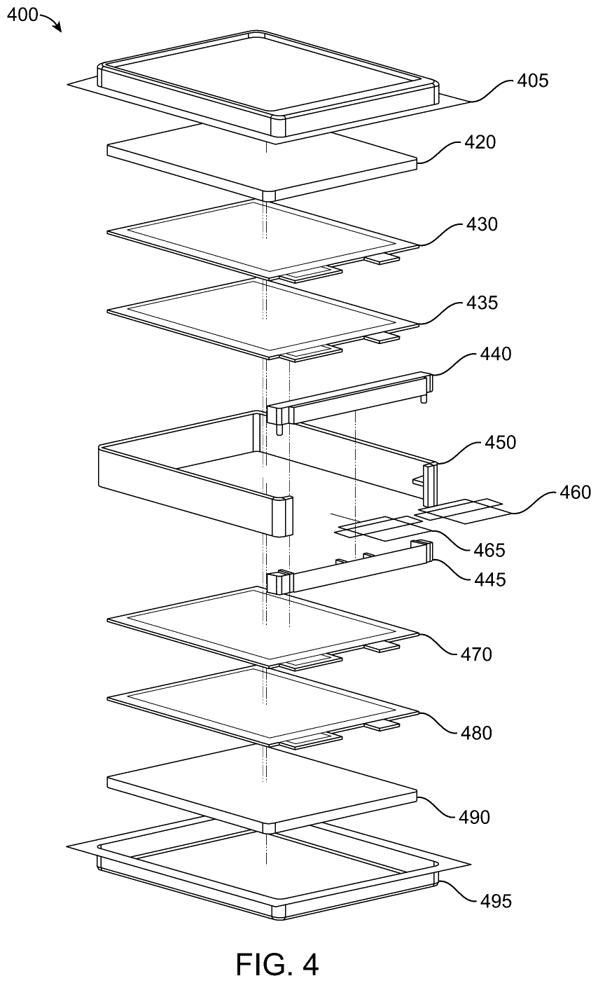

FIG. 4 is a high level exploded view of an ESA as a laminated pouch assembly 400 shown as a prismatic-frame-in-pouch, including electrochemical cells 430, 435, 470, and 480 such as those described herein according to an embodiment. Depending on the embodiment, a module may have one or more laminated pouch assemblies 400. Each ESA may comprise a plurality of electrochemical cells. In different embodiments, there may be adhesive layers (not shown) between adjacent electrochemical cells, to facilitate keeping the electrochemical cells in alignment with each other. In different embodiments, the electrochemical cells may be combined without adhesive layers, with the pressure of the rest of the laminated pouch assembly 400—including the pulling of vacuum inside the pouch, and the upper and lower laminated portions contacting the top and bottom of the frame and electrochemical stack assembly inside the pouch—keeping the electrochemical cells in alignment with each other.

Looking further at FIG. 4, laminate preforms 405, 495 form the upper and lower portions of the laminated pouch assembly 400. Spacer block 420 (which may be foam or other compressible material according to an embodiment) underlies laminate preform 405. Spacer block 490 (which also may be foam or other compressible material according to an embodiment), overlies laminate preform 450. In FIG. 4, electrochemical cells 430, 435, 470, and 470 are between spacer blocks 420 and 490. In an embodiment, frame 450 surrounds spacer blocks 420 and 490, and electrochemical cells 430, 435, 470, and 480 on three sides. On the fourth side of frame 450, top header 440 and bottom header 445 come together to enclose terminals 460, 465. Depending on the embodiment, one or both of terminals 460, 465 may be made of aluminum, or copper, or nickel-plated copper, or other suitable terminal material, as ordinarily skilled artisans will appreciate.

In an embodiment, elements 430, 435, 470, and 480 may themselves be ESAs, with the above-referenced adhesive layers coming between adjacent ESAs. Viewed in this fashion, while FIG. 4 shows four ESAs within frame 450 in laminated pouch assembly 400, ordinarily skilled artisans will appreciate that there can be more than four ESAs. Depending on the embodiment, there may be a multiple of four ESAs; there may be five ESAs or a multiple of five ESAs; there may be six ESAs or a multiple of six ESAs; there may be seven ESAs or a multiple of seven ESAs; there may be eight ESAs or a multiple of eight ESAs; there may be nine ESAs or a multiple of nine ESAs; or there may be 10 ESAs or a multiple of 10 ESAs. In some examples, there are about 100, or about 200, or about 300, or about 400, or about 500, or about 600, or about 700, or about 800, or about 900, or as many as about 1000 ESAs in a laminated pouch assembly 400.

In some examples, including any of the foregoing, a module may contain more than one laminated pouch assembly 400. In some examples, a module may contain a number of ESAs described above by containing more than one laminated pouch assembly 400.

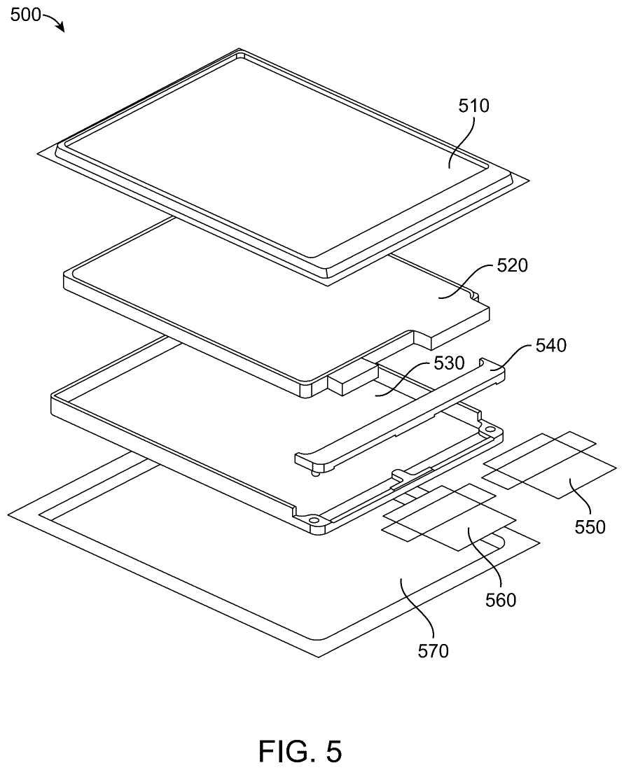

In some embodiments, a frame may comprise a center wall or center plate, such as shown in 545, as will be discussed below with respect to FIG. 5. In some embodiments, a frame does not comprise a center wall or center plate, such as shown in frame 450 in FIG. 4.

FIG. 5 shows a high level exploded view of a laminated pouch assembly 500 according to an embodiment, In FIG. 5, laminate preforms 510, 570 form the upper and lower portions of the laminated pouch assembly 500. An electrochemical cell stack 520, comprising one or more electrochemical cells, underlies laminate preform 510. Depending on the embodiment, a module may have one or more laminated pouch assemblies 500. In different embodiments, there may be adhesive layers (not shown) between adjacent electrochemical cells or electrochemical stacks, to facilitate keeping the electrochemical cells or stacks in alignment with each other. In different embodiments, the electrochemical cells or stacks may be combined without adhesive layers, with the pressure of the rest of the laminated pouch assembly 500—including the pulling of vacuum inside the pouch, and the upper and lower laminated portions contacting the top and bottom of the frame and electrochemical stack assembly inside the pouch—keeping the electrochemical cells or stacks in alignment with each other. In an embodiment, electrochemical stack 520 may itself be an ESA, with the above-referenced adhesive layers coming between adjacent ESAs.

Looking further at FIG. 5, a cooling or center plate 540 overlies laminate preform 570. The plate 540 is open at one end. Terminals 550, 560 overlie the open end of plate 540, and extend outside of laminate preforms 510, 570 when the two preforms are sealed at their edges. Header piece 530 overlies terminals 550, 560, and closes off an opening at one end of plate 540 where the terminals 550, 560 are located. Depending on the embodiment, one or both of terminals 550, 560 may be made of aluminum, or copper, or nickel-plated copper, or other suitable terminal material, as ordinarily skilled artisans will appreciate.

In some examples herein, a laminate over frame assembly comprises at least two electrochemical cells. In some examples herein, a laminate over frame assembly comprises at least 2, 4, 6, 8, 10, 20, 30, 40, 50, 60, 70, 80, 90, or more electrochemical cells. In some examples herein, a laminate over frame assembly comprises electrochemical cell stacks. In some examples herein, a laminate over frame assembly comprises electrochemical cell stacks that are arranged vertically or next to each other.

In some examples, including any of the foregoing, one of the at least two ESAs in the module has a thickness that is larger than the thickness of another one of the at least two ESAs in the module.

In some examples, including any of the foregoing, one of the at least two ESAs in the module has a thickness which is at least twice the thickness of the another one of the at least two ESA in the module.

In some examples, including any of the foregoing, the laminated pouches are close-packed.

In some examples, including any of the foregoing, the laminated pouches provide dimensional stability to the module.

In some examples, including any of the foregoing, the module is a prismatic design with smooth external faces or major surfaces.

In some examples, including any of the foregoing, the laminated pouches are stacked to minimize natural harmonic bending modes.

In some examples, including any of the foregoing, the laminated pouches are vertically stacked.

In some examples, including any of the foregoing, the module is the maximum length which minimizes natural harmonic bending modes.

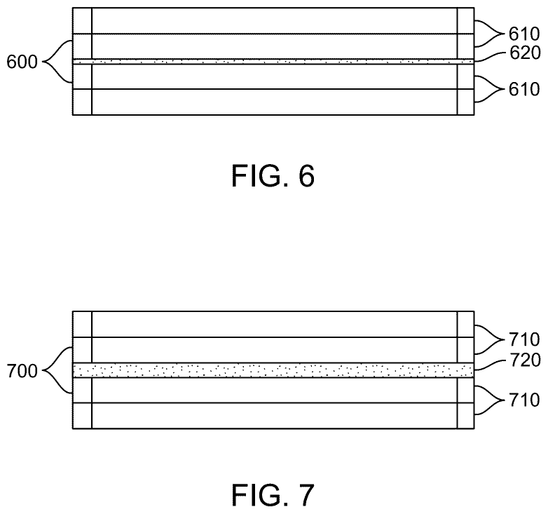

In some examples, including any of the foregoing, the module includes a compliant cooling plate between adjacent laminated pouches. In some examples, the compliant cooling plate is a metal. In some examples, the compliant cooling plate acts as a center wall for adjacent laminated pouches. FIG. 6 shows a module with a compliant cooling plate 620 between adjacent laminated pouches 600. Each laminated pouch 600 includes two or more ESAs 610. In some embodiments, laminated pouch 600 may be a prismatic-frame-in-pouch as shown in FIG. 4. Depending on the embodiment, a module may have two laminated pouches, as FIG. 6 shows, or may have more than two laminated pouches. Where there are more than two laminated pouches, there may or may not be more than one compliant cooling plate 620.

In some examples, including any of the foregoing, the module includes a compressible cooling pouch or pocket containing a cooling fluid, the pouch or pocket being disposed between adjacent laminated pouches. FIG. 7 shows a module with a compressible cooling pouch or pocket 720 between adjacent laminated pouches 700. Each laminated pouch 700 includes two more ESAs 710. As described above, the compressible cooling pouch or pocket may be coupled to a cooling system. Depending on the embodiment, a module may have two laminated pouches, as FIG. 7 shows, or may have more than two laminated pouches. Where there are more than two laminated pouches, there may or may not be more than one compressible cooling pouch or pocket 720.

In some examples, including any of the foregoing, cooling plate 620 may have one or more conduits running through it to convey a cooling fluid to provide further cooling. A cooling system may be coupled to ends of the one or more conduits.

In some examples, including any of the foregoing, the module includes about 20-100 solid-state electrolytes per ESA. In some examples, including any of the foregoing, the module includes about 60 solid-state electrolytes per ESA. In some examples, including any of the foregoing, the module includes about 80 solid-state electrolytes per ESA. In some examples, including any of the foregoing, the module includes about 100 solid-state electrolytes per ESA.

In some examples, including any of the foregoing, the pack includes about 100,000 solid-state electrolytes.

In some examples, including any of the foregoing, the module has a capacity of about 100 kWh.

In some examples, including any of the foregoing, the module comprises about 1000 ESAs.

In some examples, including any of the foregoing, the laminated pouches are pressurized to 300 Pa or other pressure sufficiently different from pressure outside the laminated pouch to cause the upper and lower portions of the laminated pouch to contact elements inside the pouch.

In some examples, including any of the foregoing, the laminated pouches do not have external pressure applied thereto. In some examples, including any of the foregoing, the laminated pouches are subject to atmospheric pressure only.

In some examples, including any of the foregoing, the electrodes or tabs are configured to vent in a safety event.

In some examples, including any of the foregoing, seals around the tabs or electrodes are configured to vent in a safety event.

In some examples, including any of the foregoing, the module includes laminated pouches positioned flat with respect to the ground.

In some examples, including any of the foregoing, the module includes laminated pouches sized and/or oriented to enable attachment to a skateboard, for example in a skateboard pack design. With respect to orientation, the pouches could be stacked vertically, or arranged horizontally, for example, along a bottom surface of a skateboard.

In some examples, including any of the foregoing, the module includes laminated pouches sized and/or oriented to enable placement in a body of a motor vehicle or a body of a motorcycle. In some examples, including any of the foregoing, the module includes laminated pouches sized and/or oriented to enable placement in the consumer electronics listed above.

In some examples, including any of the foregoing, the module includes at least two laminated pouches of different sizes.

### Laminated Pouch Assembly

In addition to the foregoing description, a non-limiting example of laminated pouch assembly is provided as follows. Ordinarily skilled artisans will appreciate that other methods of assembly are possible.

The laminated pouch assembly protects a prismatic battery cell with a perimeter (mechanical structure) frame. The prismatic battery cell may be in a stack of cells which are vacuumed, seam-sealed, and in a laminated pouch. The laminated pouch may have electrical terminals protruding outside of the laminated pouch. The resulting prismatic-frame-in-pouch protects the prismatic battery cell.

In some embodiments, a cell comprising a solid-state cathode is packaged in an electrochemical stack disclosed herein. In some embodiments, a cell comprising a cathode, wherein the cathode comprises a solid-state catholyte, is packaged in an electrochemical stack disclosed herein.

In certain examples, an electrochemical stack is provided which includes a series of electrochemical cells arranged in series. In certain other examples, an electrochemical stack is provided which includes a series of electrochemical cells arranged in parallel.

In some examples, including any of the foregoing, the electrochemical cells include a lithium-metal negative electrode. In some examples, including any of the foregoing, the electrochemical cells include a solid-state electrolyte.

In some examples, including any of the foregoing, the electrochemical cells include a solid-state electrolyte separator comprising a lithium-stuffed garnet.

In some examples, including any of the foregoing, positive and negative electrode terminals are attached to the electrochemical stack.

The electrochemical stack is bonded by way of a pressure-sensitive adhesive to a bonding plate which is also part of one half of the frame.

In certain examples, the electrochemical stack is attached at either top major surface or bottom major surface to a surface on the frame by way of a pressure-sensitive adhesive (PSA) material. This PSA holds the stack by way of either top major surface or bottom major surface to a surface from moving within the frame during charging and discharging. The PSA keeps the minor surfaces of the electrochemical stack from touching the frame. In certain examples, the top major surface is bonded to the frame at the center wall. In certain examples, the bottom major surface is bonded to the frame at the center wall. In some examples, there is no center wall. In that event, the stacks may be adhered to each other with PSA.

In an embodiment in which there are two frame pieces, the other half of the frame is connected to and attached to the above one half of the frame.

In some examples, including any of the foregoing, a laminate is manufactured into a formed shape. In some examples, the shape matches the shape of the electrochemical stack. In some examples, including any of the foregoing, the laminate has multiple layers. In certain examples, the laminate has five layers. In some of these examples, the multiple layers include a polyester (PET) layer that is adjacent to an oriented nylon (ONy) layer. The ONy layer is adjacent to an aluminum layer. The aluminum layer is adjacent to a non-adhesive sealing chemical bond polyphthalamide (PPa) layer. The PPa layer is adjacent to a polypropylene (PP) layer. In some examples, the order of these layers may be varied. In some examples, there may be more than five layers, some or all of which may be one or more of the five just-mentioned materials. In some examples, including any of the foregoing, there may be fewer than five layers, some or all of which may be one or more of the five just-mentioned materials.

In some examples, including any of the foregoing, the polymeric materials on either side of the aluminum may comprise one or more of polypropylene (PP), polyphthalamide (PPa), polyethylene terephthalate (PET), and oriented nylon (ONy).

The laminate may be manufactured from a flat sheet form. This form is placed in a pneumatic press. A die and a cavity are used to transform the flat sheet into a pre-formed shape. This includes debossing the form to raise part of the laminate up and away from the laminate surface as well as embossing the form to push part of the laminate down and away from the laminate surface. A combination of deboss and emboss is used to form the shape in the laminate. By forming a shape in the laminate, the laminate does not need to deform against either major surface of the electrochemical stack when a vacuum is pulled on a sealed laminate. The laminate is thus pre-stressed during its manufacture so no stress is concentrated on the electrochemical stack when the laminate is stretched over the frame. As the laminate is pulled over the frame, a draft angle is present as the laminate stretches over the frame. This draft angle in part provides space between the laminate and the electrochemical stack so that the laminate only contacts one or both of the major surface of the electrochemical stack.

In some examples, including any of the foregoing, a pneumatic press machine with a forming die and cavity is used.

The laminate of a laminate pouch is sealed. This bonded seal may be made by a heat sealing method. In some heat sealing methods, two hot metal bars press two laminate pouch pieces together until a polymer layer on each laminate melts and bonds (e.g., welds) the two sheets together.

A vacuum is pulled on the sealed laminate so the draft angles collapse against the frame but not against the minor surfaces of the electrochemical stack. After pulling a vacuum in the sealed laminate, the pre-formed portion of the laminate will take the shape of the frame.

### Packs

Set forth herein are packs which include at least one module set forth herein. The modules may be arranged vertically, or next to each other.

### Methods

In an embodiment, set forth herein is a method of determining state-of-charge (SOC), comprising, measuring the thickness of a laminated pouch in a module, which is described herein, wherein the thickness is proportional to the SOC; and determining SOC based on the measured thickness. In certain examples, the measuring comprises using a strain gauge.

In some examples, including any of the foregoing, the method includes acquiring historical displacement data regarding cycles of charging and discharging of electrochemical cells in the module and determining state-of-health (SOH) based on the historical displacement data.

In an embodiment, set forth herein is a method of pumping a coolant, comprising providing a module, which is described herein, wherein between laminated pouches there is a compressible cooling pouch or pocket comprising cooling fluid and coupled to a cooling system; expanding and contracting laminated pouches by charging and discharging the electrochemical cells therein; and using the mechanical force created by the laminated pouches to pump the cooling fluid.

In an embodiment, set forth herein is a method of cooling a module, which is described herein, comprising drawing heat from the ESA through the tabs. In some examples, the cooling is concurrent with a fast charge event.

In an embodiment, set forth herein is a method of cooling a module, which is described herein, comprising drawing heat from the ESA through the edges of the laminated pouches. In some examples, the cooling is concurrent with a fast charge event. In other examples, the edges are the bottom edges. In still other examples, the edges are the side edges.

In an embodiment, set forth herein is a method of cooling a module, which is described herein, comprising drawing heat from the electrochemical cells through the sides of the laminated pouches. In other examples, the cooling is concurrent with a fast charge event.

In an embodiment, set forth herein is a method of cooling a module, which is described herein, comprising drawing heat from the electrochemical cells through the faces or major surfaces of the laminated pouches. In other examples, the cooling is concurrent with a fast charge event.

### EXAMPLES

### Example 1

An assembled cell stack, including at least one cathode current collector, at least one cathode with liquid electrolyte, at least one separator, and at least one anode current collector, is provided. A foam block is added to the top of the cell stack is added so that the foam is aligned with the rest of the cell stack. Current collector tabs are welded.

A half-laminated pouch is placed on the top side of the cell stack. The cell stack is flipped. After flipping, another half-laminated pouch is placed on top of the cell stack. The edges of the two half-laminated pouches then are sealed to each other.

The embodiments and examples described above are intended to be merely illustrative and non-limiting. Those skilled in the art will recognize or will be able to ascertain using no more than routine experimentation, numerous equivalents of specific compounds, materials and procedures. All such equivalents are considered to be within the scope and are encompassed by the appended claims.

What is claimed is:

1. A module comprising at least two electrochemical stack assemblies (ESA), wherein each ESA comprises:
one or more electrochemical cells, each electrochemical cell comprising a solid-state electrolyte;
a frame surrounding the one or more electrochemical cells; and
a laminated pouch surrounding the frame and the one or more electrochemical cells;
the module further comprising a compliant cooling plate or compressible cooling pouch between adjacent laminated pouches.

2. The module of claim 1, comprising an alignment segment which interfaces with side or bottom edges of the laminated pouches.

3. The module of claim 1 or claim 2, wherein the frame is a structural support for the module.

4. The module of claim 3, wherein the structural support is selected from the group consisting of an airplane wing strut, a motorcycle body, and a motor vehicle body.

5. The module of claim 3, wherein the structural support is a component of a honeycomb structure.

6. The module of any of claims 1-5, wherein the frame has three sides, the module further comprising a header closing off a fourth side of the frame.

7. The module of any one of claims 1-6, wherein one of the at least two ESAs in the module has a thickness that is larger than the thickness of another one of the at least two ESAs in the module.

8. The module of any one of claims 1-7, wherein the laminated pouches are disposed in close-packed arrangement to minimize vacant space between adjacent laminated pouches.

9. The module of any of claims 1-8, wherein the laminated pouches provide dimensional stability to the module.

10. The module of any of claims 1-9, wherein the laminated pouches are vertically stacked in the module.

11. The module of any one of claims 1-9, wherein the laminated pouches are horizontally arrayed in the module.

12. The module of claim 11, wherein the compliant cooling plate comprises a metal.

13. The module of any one of claims 1-10, wherein the compressible cooling pouch contains a cooling fluid.

14. The module of any one of claims 1-13, comprising from about 10 to about 1000 ESAs.

15. The module of any one of claims 1-14, wherein the module has a capacity of about 100 kWh.

16. The module of any one of claims 1-15, wherein the laminated pouches are pressurized to an internal pressure of 300 Pascals (Pa).

17. The module of any one of claims 1-16, comprising laminated pouches positioned flat with respect to the ground.

18. The module of any one of claims 1-16, comprising laminated pouches oriented in a skateboard pack design.

19. The module of any one of claims 1-18, comprising at least two laminated pouches of different sizes.

20. The module of claim 1, wherein the frame comprises a center wall or center plate.

21. The module of claim 20, wherein the one or more electrochemical cells are disposed within the frame comprising a center wall or center plate.

22. The module of claim 20 or 21, wherein the frame comprising a center wall or center plate is adjacent to at least a portion of the laminated pouch.

23. The module of claim 20 or 21, wherein the frame comprising a center wall or center plate is adjacent to a major face of the laminated pouch.

24. The module of claim 1, wherein the frame does not comprise a center wall or center plate.

25. A method of determining state-of-charge (SOC), comprising,
measuring the thickness of a laminated pouch in a module of any one of claims 1-24,
wherein the thickness is proportional to the SOC; and
determining SOC based on the measured thickness.

26. The method of claim 25, wherein the measuring comprises using a strain gauge.

27. The method of claim 25 or claim 26, further comprising acquiring historical displacement data regarding cycles of charging and discharging of electrochemical cells in the module and determining state-of-health (SOH) based on the historical displacement data.

28. A method of pumping a coolant, comprising
providing a compressible cooling pouch or pocket containing cooling fluid and coupled to a cooling system, the compressible cooling pouch or pocket being disposed between adjacent laminated pouches in a module of any one of claims 1-24;
expanding and contracting the laminated pouches by charging and discharging the electrochemical cells therein; and
using mechanical force created by the expansion and contraction of the laminated pouches to pump the cooling fluid.

29. A method of cooling a module of any one of claims 1-24, comprising drawing heat from the ESAs through the tabs.

30. The method of claim 28, wherein the cooling is concurrent with a fast charge event.

31. A method of cooling a module of any one of claims 1-24, comprising drawing heat from the ESA through side or bottom edges of the laminated pouches.

32. The method of claim 31, wherein the cooling is concurrent with a fast charge.

33. A method of cooling a module of any one of claims 1-24, comprising drawing heat from the electrochemical cells through side or bottom edges of the laminated pouches.

34. The method of claim 33, wherein the sides are faces of the laminated pouch.

35. The method of claim 28 or 29, wherein the cooling is concurrent with a fast charge event.
